(19) United States
(12) Patent Application Publication
(10) Pub. No.: US 2025/0374457 A1
(43) Pub. Date: Dec. 4, 2025

(54) ELECTRONIC DEVICE AND HANDLE ASSEMBLY

(71) Applicants: INVENTEC (PUDONG) TECHNOLOGY CORPORATION, Shanghai (CN); INVENTEC CORPORATION, Taipei City (TW)

(72) Inventors: Ti WU, Taipei City (TW); Yung Chang LIN, Taipei City (TW); Chia Chi FAN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/220,237

(22) Filed: May 28, 2025

Related U.S. Application Data
(60) Provisional application No. 63/654,814, filed on May 31, 2024.

(51) Int. Cl. H05K 5/02; H05K 7/14

(52) U.S. Cl. CPC H05K 5/023; H05K 7/1487

(57) ABSTRACT

An electronic device includes a rack, at least one cage, at least one handle assembly and at least one host. The cage is disposed in the rack. The handle assembly includes a fixing member, a restoring member and a movable handle. The fixing member is disposed on a side of the at least one cage. An end of the restoring member is disposed on the fixing member. An end of the movable handle is rotatably disposed on the fixing member. Another end of the movable handle is detachably disposed on another side of the cage to press another end of the restoring member. The host is removably disposed in the cage. The restoring member restores via the movable handle released from the cage to force the movable handle to be rotated along a direction away from the cage.

### CROSS-REFERENCE TO RELATED APPLICATIONS

This non-provisional application claims priority under 35 U.S.C. § 119 (a) on Patent Application No(s). 63/654,814 filed in US, on May 31, 2024, the entire contents of which are hereby incorporated by reference.

### BACKGROUND OF THE INVENTION

### Technical Field of the Invention

The invention relates to an electronic device and a handle assembly, more particularly to an electronic device and a handle assembly having a restoring member.

### Description of the Related Art

Nowadays, with the rapid development of the information technology, most of enterprises may do various tasks on the business via a server, such as storing data. Accordingly, the efficiency of doing tasks on the business is improved.

Generally, the server may be disposed in a rack, and are facilitated to be placed in a particular position via a movable handle. However, the conventional movable handle needs to be manually unlocked from the rack before being opened, and an opening angle of the movable handle is limited. Accordingly, an interference between the server and the rack may be caused during installation or removal of the server, and an improper installation or removal of the server may be caused. Moreover, the server may even be damaged. In addition, it is needed to ensured that the conventional movable handle is unlocked from the rack before the conventional movable handle is opened, which causes operational inconvenience. Therefore, improving the convenience of installing the server and operating the movable handle is one of the key issues that researchers need to address.

### SUMMARY OF THE INVENTION

The invention provides an electronic device and a handle assembly in order to improve the convenience of installing a host and operating a movable handle.

One embodiment of the invention provides an electronic device including a rack, at least one cage, at least one handle assembly and at least one host. The at least one cage is disposed in the rack. The at least one handle assembly includes a fixing member, a restoring member and a movable handle. The fixing member is disposed on a side of the at least one cage. An end of the restoring member is disposed on the fixing member. An end of the movable handle is rotatably disposed on the fixing member. Another end of the movable handle is detachably disposed on another side of the at least one cage to press another end of the restoring member. The at least one host is removably disposed in the at least one cage. The restoring member restores via the movable handle released from the at least one cage to force the movable handle to be rotated along a direction away from the at least one cage.

Another embodiment of the invention provides a handle assembly configured to be disposed on a cage. The handle assembly includes a fixing member, a restoring member and a movable handle. The fixing member is configured be disposed on a side of the at least one cage. An end of the restoring member is disposed on the fixing member. An end of the movable handle is rotatably disposed on the fixing member. Another end of the movable handle is configured to be detachably disposed on another side of the at least one cage to press another end of the restoring member. The restoring member restores via the movable handle configured to be released from the at least one cage to force the movable handle to be rotated along a direction away from the at least one cage.

According to the electronic device and the handle assembly disclosed in the above embodiment, each of the handle assemblies includes the first restoring member. Therefore, when the latch member is disengaged from the cage, an end of the movable handle with the latch member can accordingly pop out along the direction away from the cage via the restoring of the first restoring member, and it is ensured that an opening angle of the movable handle is sufficient for assembling or disassembling the hosts. Accordingly, the convenience of assembling the hosts and operating the movable handle can be improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of an electronic device in accordance with an embodiment of the invention;

FIG. 2 is an enlarged perspective view of the electronic device in FIG. 1;

FIG. 3 is a perspective view of a handle assembly of the electronic device in FIG. 1;

FIG. 4 is an exploded view of the handle assembly of the electronic device in FIG. 1;

FIG. 5 is another exploded view of the handle assembly of the electronic device in FIG. 4;

FIG. 6 is another exploded view of the handle assembly of the electronic device in FIG. 5;

FIG. 7 is a plane view showing that an end of a movable handle of the electronic device in FIG. 1 is engaged with a cage of the electronic device in FIG. 1;

FIG. 8 is a plane view showing that the end of the movable handle of the electronic device in FIG. 1 is released from the cage of the electronic device in FIG. 1;

FIG. 9 is a plane view showing a first stage of the rotation of the movable handle of the electronic device in FIG. 1;

FIG. 10 is a perspective view showing the first stage of the rotation of the movable handle of the electronic device in FIG. 1;

FIG. 11 is a perspective view showing a second stage of the rotation of the movable handle of the electronic device in FIG. 1; and

FIG. 12 is a plane view showing the second stage of the rotation of the movable handle of the electronic device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

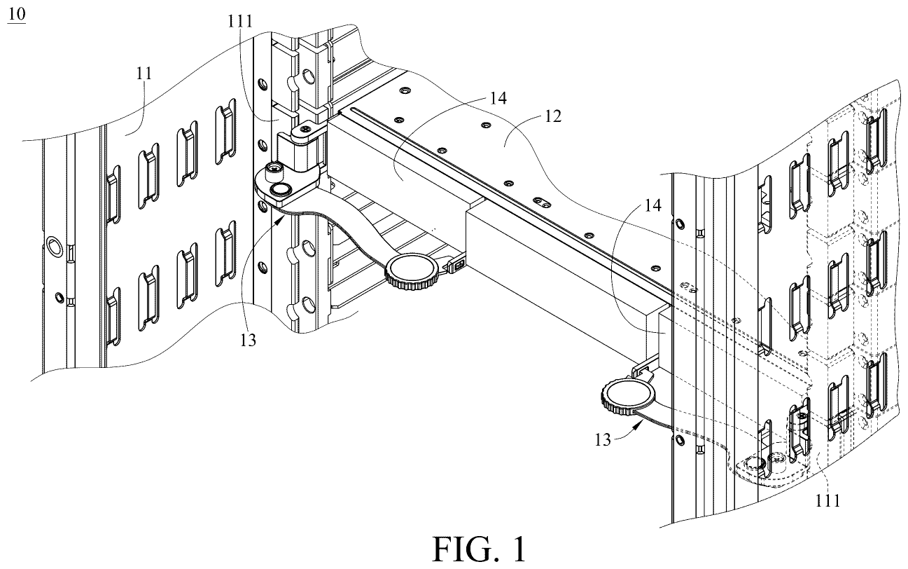

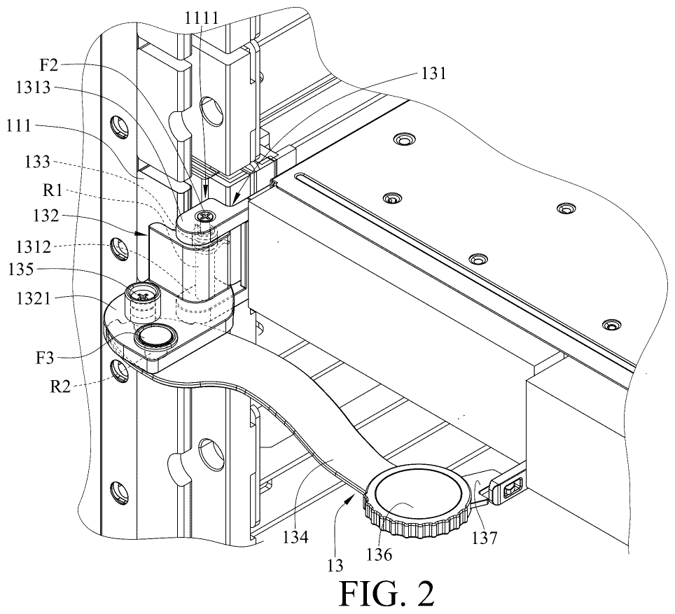

Please refer to FIG. 1 and FIG. 2, where FIG. 1 is a perspective view of an electronic device 10 in accordance with an embodiment of the invention, and FIG. 2 is an enlarged perspective view of the electronic device 10 in FIG. 1.

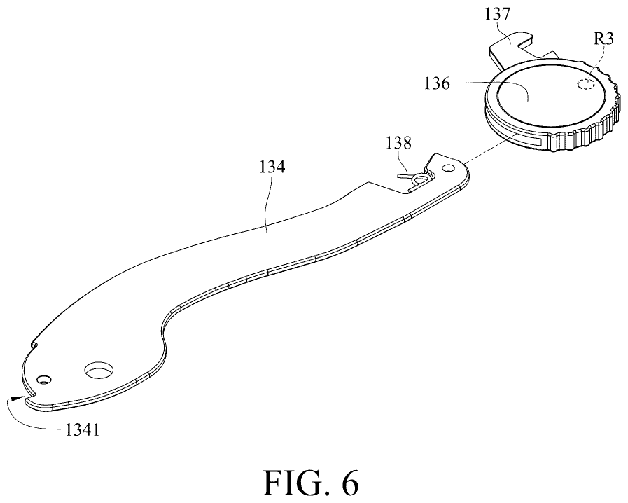

In this embodiment, the electronic device 10 includes a rack 11, a cage 12, a plurality of handle assemblies 13 and a plurality of hosts 14. The cage 12 is disposed in the rack 11, and the hosts 14 are removably disposed in the cage 12. The hosts 14 are, for example, servers. Each of the handle assemblies 13 includes a fixing member 131, a rotatable member 132, a first restoring member 133, a movable handle 134, a movable fastener 135, a handheld member 136, a latch member 137 and a second restoring member 138 (please refer to FIG. 6 temporarily).

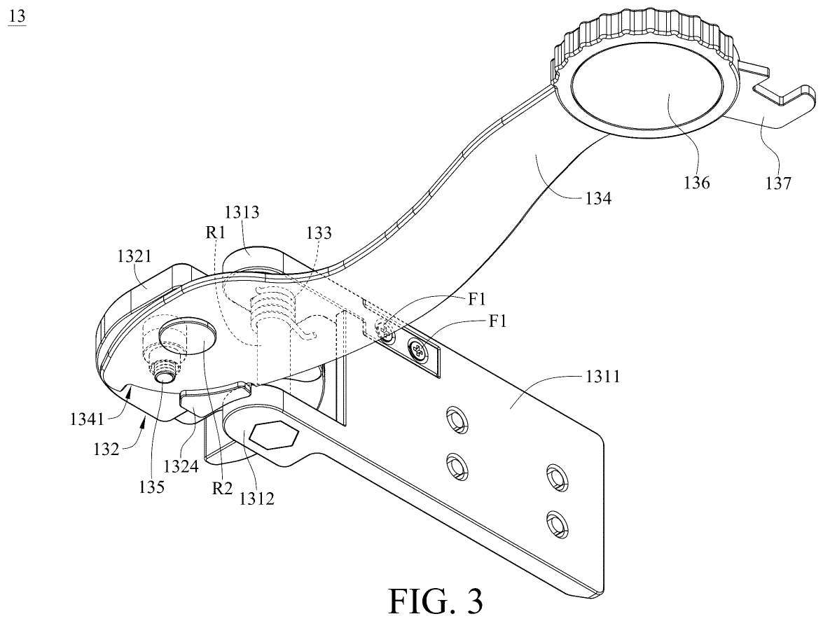

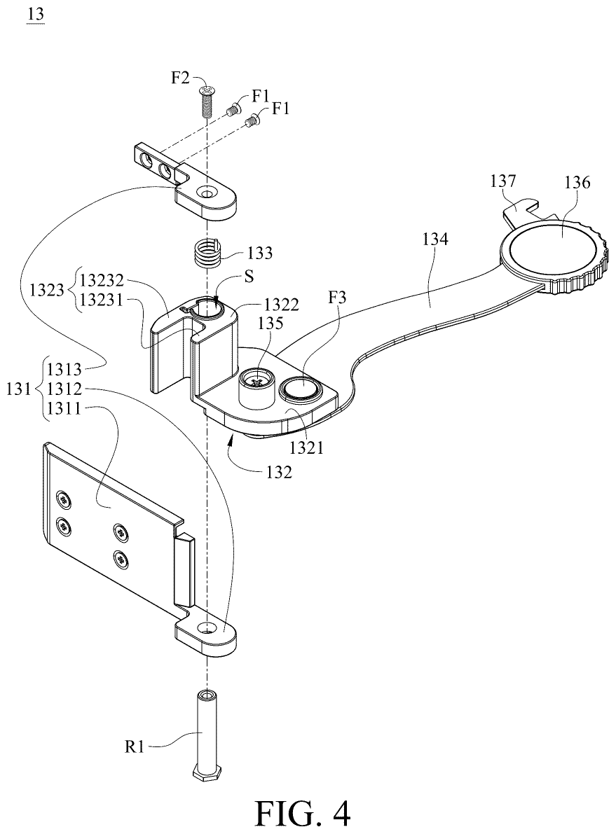

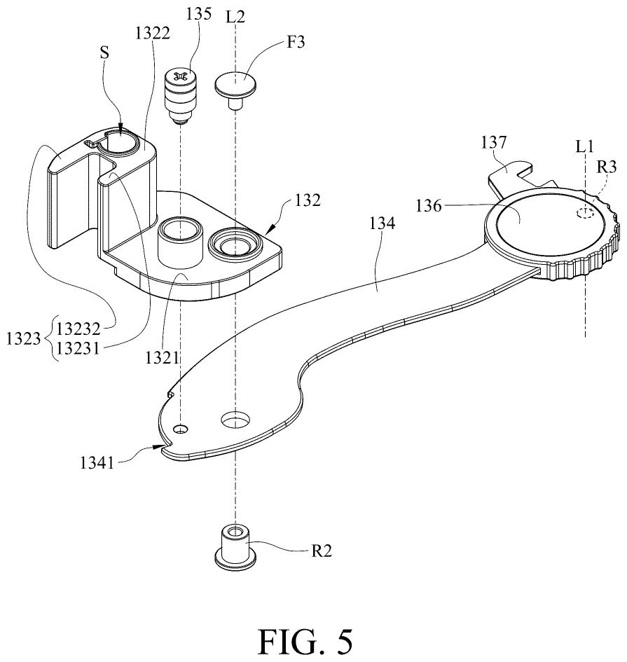

Please refer to FIG. 1 to FIG. 6, where FIG. 3 is a perspective view of the handle assembly 13 of the electronic device 10 in FIG. 1, FIG. 4 is an exploded view of the handle assembly 13 of the electronic device 10 in FIG. 1, FIG. 5 is another exploded view of the handle assembly 13 of the electronic device 10 in FIG. 4, and FIG. 6 is another exploded view of the handle assembly 13 of the electronic device 10 in FIG. 5.

The fixing member 131 is disposed on a side of the cage 12. The rotatable member 132 is rotatably disposed on the fixing member 131. Specifically, the fixing member 131 includes a side portion 1311, a bottom portion 1312 and a top portion 1313. The side portion 1311 is connected to the bottom portion 1312. The side portion 1311 is disposed on the cage 12. The rotatable member 132 includes an assembling portion 1321, a pivoting portion 1322 and a first engaging portion 1323. The pivoting portion 1322 is connected to the assembling portion 1321. The movable handle 134 is rotatably disposed on the assembling portion 1321, the pivoting portion 1322 is rotatably disposed on the bottom portion 1312.

The first engaging portion 1323 includes a contacting protrusion 13231 and an engaging protrusion 13232. The contacting protrusion 13231 and the engaging protrusion 13232 are connected to different sides of the pivoting portion 1322. The rack 11 includes a plurality of second engaging portions 111. Each of the second engaging portions 111 includes an engaging recess 1111. The contacting protrusion 13231 is configured to be in contact with one of the second engaging portions 111, and the engaging protrusion 13232 is configured to be engaged with the engaging recess 1111. Accordingly, the first engaging portion 1323 can be engaged with one of the second engaging portions 111 or be released from one of the second engaging portions 111.

The first engaging portion 1323 includes an accommodating space S. Different sides of the top portion 1313 are disposed on the side portion 1311 and the first engaging portion 1323, respectively. The top portion 1313 covers the accommodating space S. The first restoring member 133 is, for example, a torsional spring, and is located in the accommodating space S. An end of the first restoring member 133 is disposed on the top portion 1313. Another end of the first restoring member 133 is disposed on the pivoting portion 1322.

An end of the movable handle 134 is movably disposed on the fixing member 131 via the rotatable member 132. Another end of the movable handle 134 is detachably disposed on another side of the cage 12, such that the pivoting portion 1322 of the rotatable member 132 is configured to press an end of the first restoring member 133 away from the fixing member 131. Accordingly, the first restoring member 133 stores elastic potential energy.

The movable fastener 135 is, for example, a captive screw, and is movably disposed on the rotatable member 132. The movable fastener 135 is optionally disposed through the movable handle 134 to force the movable handle 134 to be rotated relative to the fixing member 131 or the rotatable member 132. Accordingly, the movable handle 134 is enabled to perform a two-stage rotation. Specifically, the movable handle 134 can perform a first stage of rotation relative to the fixing member 131, and can perform a second stage of rotation relative to the rotatable member 132.

The handheld member 136 is, for example, a knob, and is rotatably disposed on another end of the movable handle 134. A rotational axis L1 about which the handheld member 136 is rotated relative to the movable handle 134 is, for example, parallel to a rotational axis L2 about which the movable handle 134 is rotated relative to the rotatable member 132.

The latch member 137 is disposed on the handheld member 136. The second restoring member 138 is, for example, a torsional spring, and is disposed between the handheld member 136 and the latch member 137. The latch member 137 can press the second restoring member 138 and be disengaged from another side of the cage 12 via the rotation the handheld member 136, thereby allowing the second restoring member 138 to store elastic potential energy. Alternatively, the handheld member 136 can force the latch member 137 to be engaged with another side of the cage 12 via the elastic force generated by the elastic potential energy released from the second restoring member 138. When the latch member 137 is disengaged from another side of the cage 12, the movable handle 134 is thereby released from the cage 12. Accordingly, the first restoring member 133 releases the stored elastic potential energy and restores, thereby causing the rotatable member 132 to force the movable handle 134 to be rotated along a direction away from the cage 12. That is, when the latch member 137 is disengaged from another side of the cage 12, the movable handle 134 can accordingly pop out along the direction away from the cage 12 via the rotatable member 132.

In this embodiment, the rotatable member 132 may include a first limiting structure 1324. The first limiting structure 1324 is, for example, a limiting protrusion, and is disposed on the assembling portion 1321. The movable handle 134 may include a second limiting structure 1341. The second limiting structure 1341 is, for example, a limiting recess. The second limiting structure 1341 cooperates with the first limiting structure 1324 to restrict a rotation angle of the movable handle 134 at the rotatable member 132 when the movable fastener 135 is separated from the movable handle 134. Accordingly, the movable handle 134 can be prevented from hitting the rack 11 when being rotated.

In this embodiment, the electronic device 10 may include a plurality of first fasteners F1. The first fasteners F1 are, for example, screws, and are disposed through the side portion 1311 and the top portion 1313 to fix the top portion 1313 on the side portion 1311.

In this embodiment, the electronic device 10 may include a first shaft R1 and a second fastener F2. The first shaft R1 is disposed through the bottom portion 1312 and the first engaging portion 1323, and at least a part of the first shaft R1 is located in the accommodating space S, such that the rotatable member 132 can be rotated relative to the fixing member 131 via the first shaft R1. The first restoring member 133 is sleeved on the first shaft R1. The second fastener F2 is, for example, a screw, and is disposed through the top portion 1313 and the first shaft R1 to fix the top portion 1313 on the first engaging portion 1323.

In this embodiment, the electronic device 10 may include a second shaft R2 and a third fastener F3. The second shaft R2 is disposed through the assembling portion 1321 and the movable handle 134. The third fastener F3 is, for example, a screw, and is disposed through the assembling portion 1321 and the movable handle 134, such that the movable handle 134 can be rotated relative to the rotatable member 132 via the second shaft R2. That is, the movable handle 134 is rotated relative to the rotatable member 132 by the second shaft R2 about the rotational axis L2.

In this embodiment, the electronic device 10 may include a third shaft R3. The third shaft R3 is disposed through the handheld member 136 and the movable handle 134, such that the handheld member 136 can be rotated relative to the movable handle 134 via the third shaft R3. That is, the handheld member 136 is rotated relative to the movable handle 134 by the third shaft R3 about the rotational axis L1.

In this embodiment, each of the handle assemblies 13 includes the first restoring member 133, and two opposite ends of the first restoring member 133 are disposed on the fixing member 131 and the rotatable member 132. Therefore, when the latch member 137 is disengaged from the cage 12, an end of the movable handle 134 with the latch member 137 can accordingly pop out along the direction away from the cage 12 via the restoring of the first restoring member 133, and it is ensured that an opening angle of the movable handle 134 is sufficient for assembling or disassembling the hosts 14. Accordingly, the convenience of assembling the hosts 14 and operating the movable handle 134 can be improved.

In addition, each of the handle assemblies 13 includes the movable fastener 135, and the movable fastener 135 can be optionally disposed through the movable handle 134. Therefore, the movable handle 134 can be forced to be rotated relative to the fixing member 131 or the rotatable member 132, thereby enabling the movable handle 134 to perform the two-stage rotation. Accordingly, the opening angle of the movable handle 134 can be further increased, such that the convenience of assembling the hosts 14 and operating the movable handle 134 can be further improved.

Moreover, each of the handle assemblies 13 includes the handheld member 136 and the latch member 137, and the handheld member 136 is rotatably disposed on the movable handle 134. Therefore, the handheld member 136 can force the latch member 137 to be engaged with or disengaged from the cage 12 via the rotation of the handheld member 136, such that the engagement or disengagement between the latch member 137 and the cage 12 can be confirmed during the rotation of the handheld member 136. Accordingly, the convenience of assembling the hosts 14 and operating the movable handle 134 can be further improved.

In this embodiment, there is one cage 12 merely, and there are multiple hosts 14, but the invention is not limited thereto. In other embodiments, there may be multiple cages, and there may be one host merely.

In this embodiment, there are multiple handle assemblies 13 and multiple second engaging portions 111, but the invention is not limited thereto. In other embodiments, there may be one handle assembly and one second engaging portion merely.

In this embodiment, there are multiple first fasteners F1, multiple second fasteners F2 and multiple third fasteners F3, but the invention is not limited thereto. In other embodiments, there may be one first fastener, one second fastener and one third fastener merely.

In this embodiment, the first limiting structure 1324 is a limiting protrusion, and the second limiting structure 1341 is a limiting recess, but the invention is not limited thereto. In other embodiments, the recess and protrusion configurations of the first limiting structure and the second limiting structure may be exchanged. That is, the first limiting structure may be a limiting recess, and the second limiting structure may be a limiting protrusion.

In this embodiment, the handheld member 136 is a knob, and forces the latch member 137 to be engaged with the cage 12 or to be released from the cage 12 via the rotation of the handheld member 136, but the invention is not limited thereto. In other embodiments, the handheld member may force the latch member to be engaged with the cage or to be released from the cage via other way.

In this embodiment, the rotational axis L1 about which the handheld member 136 is rotated relative to the movable handle 134 is parallel to the rotational axis L2 about which the movable handle 134 is rotated relative to the rotatable member 132, but the invention is not limited thereto. In other embodiments, the rotational axis about which the handheld member is rotated relative to the movable handle may be, for example, not parallel to the rotational axis about which the movable handle is rotated relative to the rotatable member.

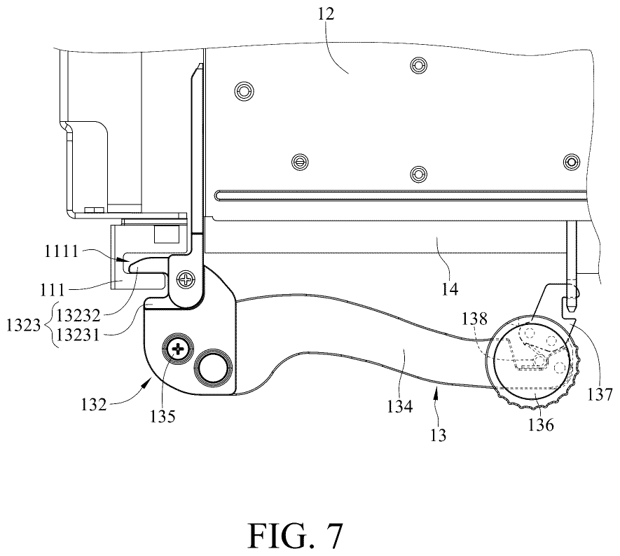

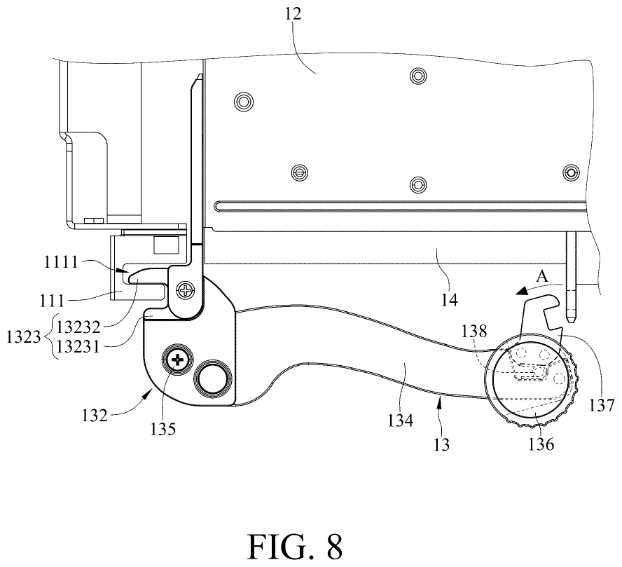

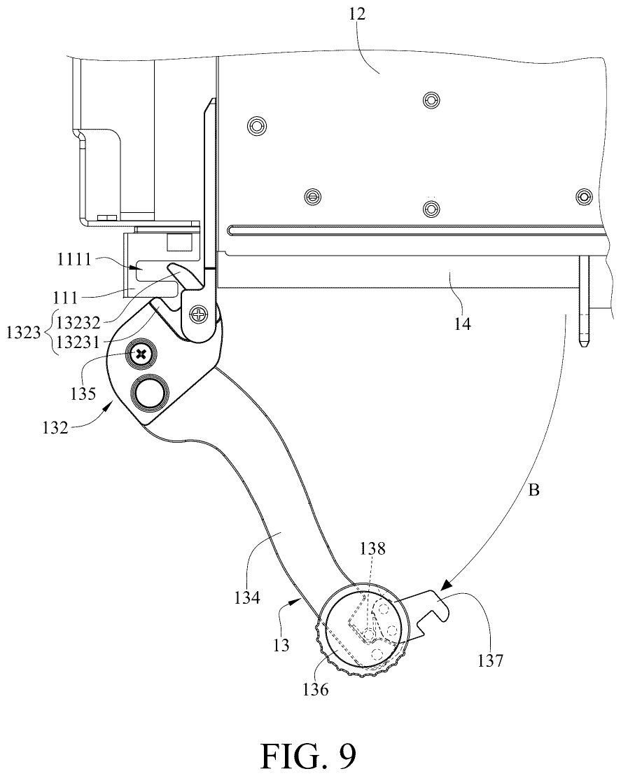

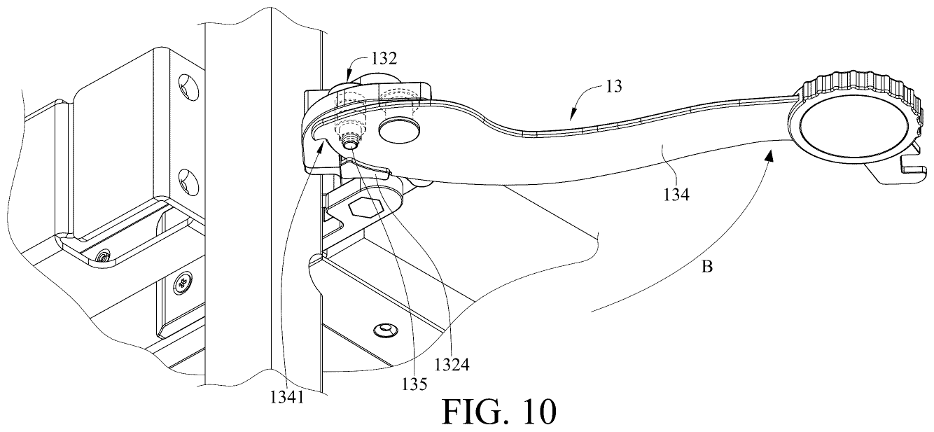

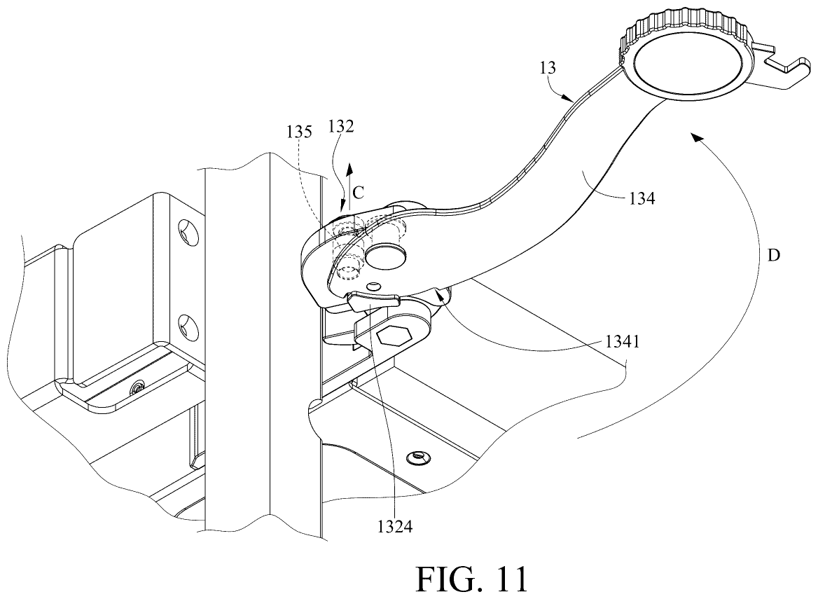

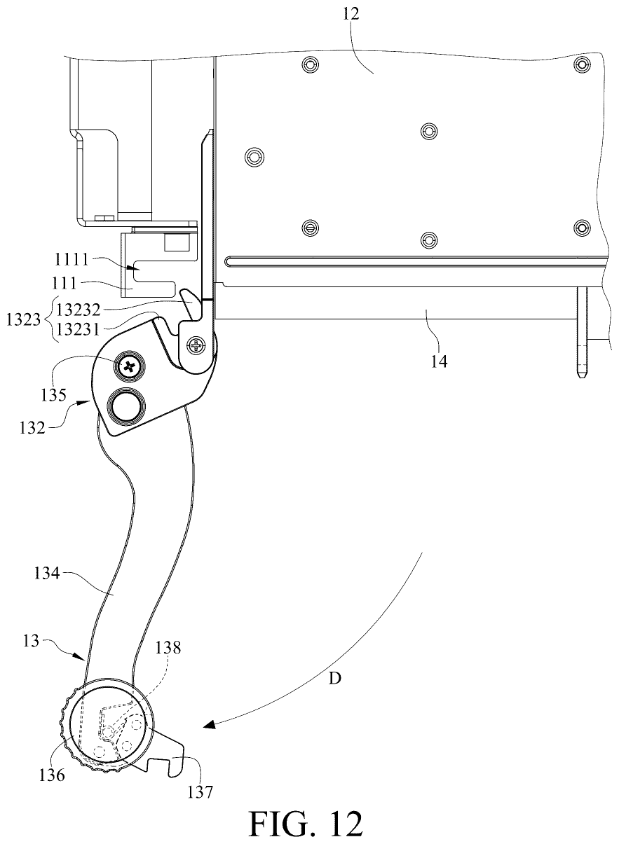

Please refer to FIG. 7 to FIG. 12, where FIG. 7 is a plane view showing that the end of the movable handle 134 of the electronic device 10 in FIG. 1 is engaged with the cage 12 of the electronic device 10 in FIG. 1, FIG. 8 is a plane view showing that the end of the movable handle 134 of the electronic device 10 in FIG. 1 is released from the cage 12 of the electronic device 10 in FIG. 1, FIG. 9 is a plane view showing a first stage of the rotation of the movable handle 134 of the electronic device 10 in FIG. 1, FIG. 10 is a perspective view showing the first stage of the rotation of the movable handle 134 of the electronic device 10 in FIG. 1, FIG. 11 is a perspective view showing a second stage of the rotation of the movable handle 134 of the electronic device 10 in FIG. 1, and FIG. 12 is a plane view showing the second stage of the rotation of the movable handle 134 of the electronic device 10 in FIG. 1.

In this embodiment, when the movable handle 134 needs to be opened for assembling or disassembling the hosts 14, as shown in FIG. 7 and FIG. 8, the handheld member 136 is rotated along a direction A, forcing the latch member 137 to be disengaged from the cage 12. Then, as shown in FIG. 9 and FIG. 10, when the latch member 137 is disengaged from the cage 12, the rotatable member 132 can force the movable handle 134 to be rotated along direction B relative to the fixing member 131 via the restoring of the first restoring member 133, such that a side of the second limiting structure 1341 is in contact with the first limiting structure 1324. Accordingly, the first stage of rotation of the movable handle 134 is completed, and the movable fastener 135 still fixes the movable handle 134 on the rotatable member 132.

Then, as shown in FIG. 11 and FIG. 12, the movable fastener 135 is moved along a direction C to release the movable handle 134, such that the movable handle 134 can be continuously rotated along a direction D relative to the rotatable member 132, and another side of the second limiting structure 1341 is in contact with the first limiting structure 1324. Accordingly, the second stage of rotation of the movable handle 134 is completed, thereby providing the sufficient opening angle of the movable handle 134 to facilitate the assembly or the disassembly of the hosts 14.

On the contrary, when the movable handle 134 needs to be closed, the movable handle 134 is rotated along a direction opposite to the direction D, and the movable fastener 135 is moved along a direction opposite to the direction C to fix the movable handle 134 on the rotatable member 132. Then, the movable handle 134 is rotated along a direction opposite to the direction B, and the handheld member 136 is rotated along the direction A, such that the latch member 137 presses the second restoring member 138, thereby allowing the second restoring member 138 to store the elastic potential energy. Then, the second restoring member 138 releases the stored elastic potential energy and thus restores along a direction opposite to the direction A, thereby forcing the latch member 137 to be engaged with another side of the cage 12 via the handheld member 136. Accordingly, the movable handle 134 can be closed.

In this embodiment, the server of the invention can be applied to artificial intelligence (AI) computing, edge computing, and can also be used as a 5G server, a cloud server or a Vehicles Internet server.

According to the electronic device and the handle assembly disclosed in the above embodiment, each of the handle assemblies includes the first restoring member, and two opposite ends of the first restoring member are disposed on the fixing member and the rotatable member. Therefore, when the latch member is disengaged from the cage, an end of the movable handle with the latch member can accordingly pop out along the direction away from the cage via the restoring of the first restoring member, and it is ensured that an opening angle of the movable handle is sufficient for assembling or disassembling the hosts. Accordingly, the convenience of assembling the hosts and operating the movable handle can be improved.

In addition, each of the handle assemblies includes the movable fastener, and the movable fastener can be optionally disposed through the movable handle. Therefore, the movable handle can be forced to be rotated relative to the fixing member or the rotatable member, thereby enabling the movable handle to perform the two-stage rotation. Accordingly, the opening angle of the movable handle can be further increased, thereby enhancing the convenience of assembling the hosts and operating the movable handle.

Moreover, each of the handle assemblies includes the handheld member and the latch member, and the handheld member is rotatably disposed on the movable handle. Therefore, the handheld member can force the latch member to be engaged with or disengaged from the cage via the rotation of the handheld member, such that the engagement or disengagement between the latch member and the cage can be confirmed during the rotation of the handheld member. Accordingly, the convenience of assembling the hosts and operating the movable handle can be further improved.

It will be apparent to those skilled in the art that various modifications and variations can be made to the invention. It is intended that the specification and examples be considered as exemplary embodiments only, with the scope of the invention being indicated by the following claims.

What is claimed is:

1. An electronic device, comprising:
a rack;
at least one cage, disposed in the rack;
at least one handle assembly, comprising:
a fixing member, disposed on a side of the at least one cage;
a restoring member, wherein an end of the restoring member is disposed on the fixing member; and
a movable handle, wherein an end of the movable handle is rotatably disposed on the fixing member, and another end of the movable handle is detachably disposed on another side of the at least one cage to press another end of the restoring member; and
at least one host, removably disposed in the at least one cage;
wherein the restoring member restores via the movable handle released from the at least one cage to force the movable handle to be rotated along a direction away from the at least one cage.

2. The electronic device according to claim 1, wherein the at least one handle assembly further comprises a rotatable member, the rotatable member is rotatably disposed on the fixing member, the movable handle is rotatably disposed on the fixing member via the rotatable member, an end of the restoring member away from the fixing member is disposed on the rotatable member to force the rotatable member to be configured to press the end of the restoring member away from the fixing member, and when the restoring member restores, the restoring member forces the movable handle to be rotated along the direction away from the at least one cage.

3. The electronic device according to claim 2, wherein the rotatable member comprises an assembling portion and a pivoting portion, the pivoting portion is connected to the assembling portion, the movable handle is disposed on the assembling member, the pivoting portion is rotatably disposed on the fixing member, and the end of the restoring member is disposed on the pivoting portion.

4. The electronic device according to claim 3, wherein the rotatable member further comprises a first engaging portion, the first engaging portion comprises a contacting protrusion and an engaging protrusion, the contacting protrusion and the engaging protrusion are connected to different sides of the pivoting portion, the rack comprises at least one second engaging portion, the at least one second engaging portion comprises an engaging recess, the contacting protrusion is configured to be in contact with the at least one second engaging portion, and the engaging protrusion is configured to be engaged with the engaging recess.

5. The electronic device according to claim 4, wherein the fixing member comprises a side portion and a bottom portion, the side portion is connected to the bottom portion, the side portion is disposed on the at least one cage, and the pivoting portion is rotatably disposed on the bottom portion.

6. The electronic device according to claim 5, wherein the first engaging portion comprises an accommodating space, the restoring member is located in the accommodating space, the fixing member further comprises a top portion, different sides of the top portion are disposed on the side portion and the first engaging portion, respectively, the top portion covers the accommodating space, and the end of the restoring member is disposed on the top portion.

7. The electronic device according to claim 6, further comprising at least one first fastener, wherein the at least one first fastener is disposed through the side portion and the top portion to fix the top portion on the side portion.

8. The electronic device according to claim 7, further comprising a shaft and a second fastener, wherein the shaft is disposed through the bottom portion and the first engaging portion, at least a part of the shaft is located in the accommodating space, the restoring member is sleeved on the shaft, and the second fastener is disposed through the top portion and the shaft to fix the top portion on the first engaging portion.

9. A handle assembly, configured to be disposed on at least one cage, comprising:
a fixing member, configured be disposed on a side of the at least one cage;
a restoring member, wherein an end of the restoring member is disposed on the fixing member; and
a movable handle, wherein an end of the movable handle is rotatably disposed on the fixing member, and another end of the movable handle is configured to be detachably disposed on another side of the at least one cage to press another end of the restoring member;
wherein the restoring member restores via the movable handle configured to be released from the at least one cage to force the movable handle to be rotated along a direction away from the at least one cage.

10. The handle assembly according to claim 9, wherein the at least one handle assembly further comprises a rotatable member, the rotatable member is rotatably disposed on the fixing member, the movable handle is rotatably disposed on the fixing member via the rotatable member, an end of the restoring member away from the fixing member is disposed on the rotatable member to force the rotatable member to be configured to press the end of the restoring member away from the fixing member, and when the restoring member restores, the restoring member forces the movable handle to be configured to be rotated along the direction away from the at least one cage.
